(19) United States
(12) Patent Application Publication
(10) Pub. No.: US 2006/0273313 A1
(43) Pub. Date: Dec. 7, 2006

(54) IC packaging technique

(75) Inventor: Chien-Yuan Chen, Banchiau City (TW)

Correspondence Address: TROXELL LAW OFFICE PLLC;SUITE 1404, 5205 LEESBURG PIKE, FALLS CHURCH, VA, 22041, US

(73) Assignee: Power Digital Card Co., Ltd. & Chien-Yuan CHEN

(21) Appl. No.: 11/140,938

(22) Filed: Jun. 1, 2005

(51) Int. Cl. H01L 23/58; H01L 29/10

(52) U.S. Cl. 257/48

(57) ABSTRACT

An IC packaging technique uses a recyclable and environmental benign plastic material (such as a thermal plastic material) to perform packaging to an IC chip, in order to solve shortcomings of an inability of being recycled of a thermosetting material, an inability of reprocessing and repairing the IC, and a generation of environmental pollution. The thermal plastic material can be a low-temperature molding material such as an ABS or a PE. More particularly, the present invention can use a conventional plastic injection machine and a recyclable thermal plastic material to perform packaging, which overcomes a technical bottleneck of industries in high pressure and high temperature, so as to increase a stability and perfection rate to the IC chip packaging process, and to meet requirements of environmental protection.

### BACKGROUND OF THE INVENTION

1. (a) Field of the Invention

The present invention relates to an IC (Integrated Circuit) packaging technique, and more particularly to a technique wherein a recyclable and environmental benign plastic material (such as a thermal plastic material) for replacing an existing thermosetting material used by industries, and especially a conventional plastic injection machine are used to package an IC chip, which not only overcomes a technical bottleneck of industries in high pressure and high temperature, but also increases a stability and perfection rate to a process of packaging, and especially meets requirements of environmental protection.

2. (b) Description of the Prior Art

As the advancement of technology in the 21st century, electronic products are developed worldwide on the basis of an IC unit. The purpose of an IC manufacturing process is to provide a set of architecture to the IC, so as to enable the IC to achieve a stable function. Techniques of IC architecture applying an IC chip mount, which are often seen in the existing market, are all limited to numbers of suitable I/O pins and a tolerable range of electronics properties. In addition, as the difference of application, the structure and material in the associated IC chip mount also has a large variation.

Therefore, the IC packaging is to establish a protection and architecture to IC elements. The packaging process begins after the IC chip manufacturing process, and includes a bonding, a wire connection, structure sealing and assembly of a circuit board, system integration, and all processes before accomplishing the products. However, the package materials can be classified into ceramic packages and plastic packages according to the properties of materials.

Raw materials of a conventional IC plastic packaging material are primarily an Epoxy and an inorganic Silica additive. Following a minimization of IC packages and a development of high density accumulation, a requirement of high temperature in lead frames and substrates becomes especially stringent. As a conventional thermosetting packaging material has a lower solidifying temperature, and it requires a high temperature to melt a thermal plastic material, an injection pressure should be taken into consideration for performing an injection molding to a plastic material requiring a high temperature processing, along with a consideration of damage to an IC circuit wiring due to a high temperature. As a thermosetting material is used to package existing IC chips, but the thermosetting material cannot be recycled for re-use, an environmental pollution will be generated definitely. As European Union will fully restrict a utilization of environmental polluting materials in the year of 2006, and many countries are defining detailed regulations to chemical products which will cause pollution now, it is an aspect of endeavor to the present inventor to develop recyclable and environmental benign thermal plastic materials, such as an ABS (Acrylonitrile Butadiene Styrene), a PE (Polyethylene), etc., in order to follow the trend.

### SUMMARY OF THE INVENTION

The primary-object of the present invention is to provide an IC packaging technique for meeting requirements of environmental protection and with a stable packaging process, wherein the packaging process includes a die bonding on an IC chip mount, a wire bonding, and a solidifying to a connection wire, followed by injecting a packaging material into a mold cavity, and a final testing and packaging. The packaging material to be injected can be a recyclable and environmental benign plastic material, i.e., a thermal plastic material, such as an ABS, a PE, to fulfill requirements of environmental protection. In addition, the packaging can be accomplished with a smaller injection pressure and a lower temperature during the process of packaging, thereby reducing a defect rate due to damage to a circuit wiring.

To enable a further understanding of the said objectives and the technological methods of the invention herein, the brief description of the drawings below is followed by the detailed description of the preferred embodiments.

### BRIEF DESCRIPTION OF THE DRAWINGS

FIG. 1 shows a flow diagram of implementation of the present invention.

FIG. 2 shows a flow diagram of another implementation of the present invention.

### DETAILED DESCRIPTION OF THE PREFERRED EMBODIMENTS

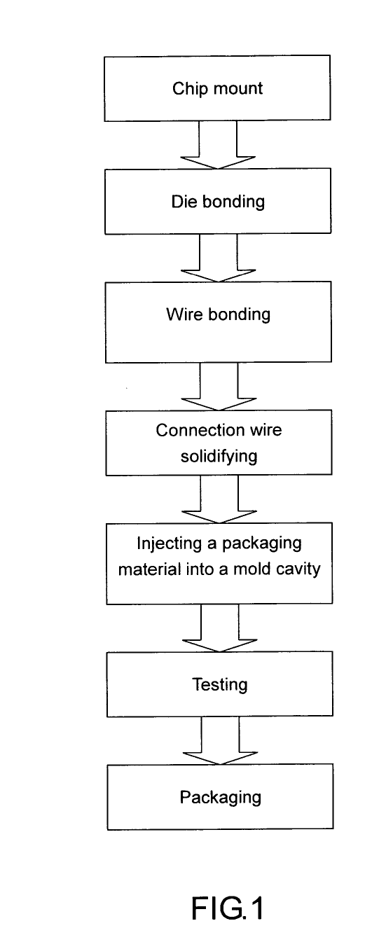

Referring to FIG. 1, it shows a flow diagram of implementation of the present invention. The IC packaging process of the present invention starts at a die bonding on a chip mount and then a wire bonding; following solidifying a connection wire, a packaging material is injected into a mold cavity, and finally a testing and packaging are performed. During the procedure of injecting the package material into the mold cavity, a thermal plastic material which meets requirements of environment protection is used for implementation.

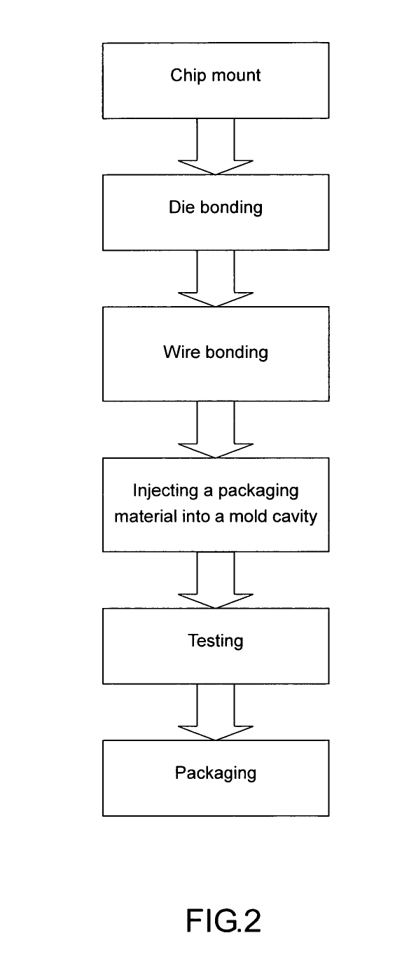

Under a condition of simple circuit wiring or that there is no concern about bonding, the engineering of solidifying the connection wire can be avoided definitely, and the injection of packaging material into the mold cavity can be proceeded directly (as shown in FIG. 2).

The IC packaging technique of the present invention actually serves as a comparison and improvement against shortcomings of a conventional packaging with a thermosetting material, as the thermosetting material is not recyclable; thereby causing a pollution to environment, whereas an injection pressure is larger and a temperature is higher for injection molding an ordinary thermosetting material, thereby generating a defect rate in the packaging process. On the other hand, the present invention uses a recyclable and environmental benign thermal plastic material, such as an ABS, a PE, etc, to replace a PVC (Polyvinyl Chloride) or a PET (Polyethylene Terephthalate) as a packaging material. During the process of packaging, after bonding and solidifying a die and wire, the packaging can be accomplished with a smaller injection pressure and a lower molding temperature, thereby reducing a risk of damaging the circuit wiring. Furthermore, as the thermal plastic material such as an ABS and a PE is a kind of decomposable and environmental benign material, it is complied more with a trend of environmental protection concepts.

It is of course to be understood that the embodiments described herein is merely illustrative of the principles of the invention and that a wide variety of modifications thereto may be effected by persons skilled in the art without departing from the spirit and scope of the invention as set forth in the following claims.

What is claimed is:

1. An IC packaging technique wherein a recyclable and environmental benign thermal plastic material is used to package an IC chip with a conventional plastic injection machine with features of thermal plastic material being able to increase a stability and perfection rate to the IC chip packaging process during the packaging process and being complied with requirements of environmental protection; the thermal plastic material being a decomposable and recyclable plastic material, and injected into a packaging mold cavity for performing packaging and molding by heat and pressure; the packaging process of the IC packaging technique starting at a die bonding on a chip mount and then a wire bonding, followed by solidifying a connection wire and then injecting a package material into a mold cavity, and finishing with a final testing and packaging.

2. The IC packaging technique according to claim 1, wherein an engineering of solidifying the connection wire in the IC packaging process can be avoided.

3. The IC packaging technique according to claim 1, wherein the thermal plastic material can be a low-temperature molding plastic material, such as an ABS and a PE.
